(19) United States
(12) Patent Application Publication
(10) Pub. No.: US 2024/0241694 A1
(43) Pub. Date: Jul. 18, 2024

(54) METHOD AND MEMORY DEVICE WITH IN-MEMORY COMPUTING

(71) Applicant: SAMSUNG ELECTRONICS CO., LTD., Suwon-si (KR)

(72) Inventors: Daekun YOON, Suwon-si (KR); Soon-Wan KWON, Suwon-si (KR); Seok Ju YUN, Suwon-si (KR); Jaehyuk LEE, Suwon-si (KR); Dong-Jin CHANG, Suwon-si (KR)

(73) Assignee: SAMSUNG ELECTRONICS CO., LTD., Suwon-si (KR)

(21) Appl. No.: 18/355,046

(22) Filed: Jul. 19, 2023

(30) Foreign Application Priority Data
Jan. 18, 2023 (KR) 10-2023-0007388

(51) Int. Cl. G06F 7/544; G06F 7/501; G11C 7/10

(52) U.S. Cl. CPC G06F 7/5443; G06F 7/501; G11C 7/1012

(57) ABSTRACT

Disclosed is an in-memory computing device and method. The in-memory computing device includes: a memory unit including bit cells configured to store first input data having a reference-bit-count, receive second input data also having the reference-bit-count, and perform a multiplication operation between the first input data and the second input data; and an operation unit including: a first adder tree configured to output intermediate operation results by adding results of performing the multiplication operation output with respect to each of the bit cells; a branch module configured to branch the intermediate operation results according to an operation mode of the in-memory computing device; and a second adder tree configured to output a final operation result based on an output of the branch module.

### CROSS-REFERENCE TO RELATED APPLICATIONS

This application claims the benefit under 35 U.S.C. § 119(a) of Korean Patent Application No. 10-2023-0007388, filed on Jan. 18, 2023, in the Korean Intellectual Property Office, the entire disclosure of which is incorporated herein by reference for all purposes.

### BACKGROUND

### 1. Field

The disclosure relates to a method and memory device with in-memory computing.

### 2. Description of Related Art

The use of deep neural networks (DNNs) is leading to an industrial revolution based on artificial intelligence (AI). A convolutional neural network (CNN), one type of DNN, is widely used in various application fields such as image and signal processing, object recognition, computer vision, etc. A CNN may be configured to perform multiply and accumulate (MAC) operations that repeat multiplication and addition using a very large number of potentially large matrices. When executing applications of a CNN using general-purpose processors, the amount of computation is exceptionally large, but simple operations such as multiply and accumulate (MAC) operations that calculate a dot product of two vectors and accumulate and sum the values, for example, may be performed through in-memory computing.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an in-memory computing device includes: a memory unit including bit cells configured to store first input data having a reference-bit-count, receive second input data also having the reference-bit-count, and perform a multiplication operation between the first input data and the second input data; and an operation unit including: a first adder tree configured to output intermediate operation results by adding results of performing the multiplication operation output with respect to each of the bit cells; a branch module configured to branch the intermediate operation results according to an operation mode of the in-memory computing device; and a second adder tree configured to output a final operation result based on an output of the branch module.

The results of performing the multiplication operation may be mapped to an input terminal of the first adder tree based on a number of operation modes.

The branch module may include: a demultiplexer configured to determine a performing path of a shift operation corresponding to each of the intermediate operation results according to the operation mode; and an adder connected to the demultiplexer to perform a shift operation corresponding to each of the intermediate operation results based on the performing path.

The operation mode may include a first operation mode and a second operation mode, the first adder tree is configured to output a first intermediate operation result and a second intermediate operation result, the branch module is configured to deliver the first intermediate operation result and the second intermediate operation result to the second adder tree according to the first operation mode, and the second adder tree is configured to output the final operation result by adding the first intermediate operation result to the second intermediate operation result.

The operation mode may include a first operation mode and a second operation mode, the first adder tree is configured to output a first intermediate operation result and a second intermediate operation result, the branch module may be configured to deliver the first intermediate operation result and the second intermediate operation result shifted by the reference-bit-count to the second adder tree according to the second operation mode, and the second adder tree may be configured to output the final operation result by adding the first intermediate operation result to the shifted second intermediate operation result.

The operation unit may be configured to perform different bit-number operations depending on the operation mode.

A number of operation modes may be determined based on a maximum bit number of an operable bit number and a bit number of the reference-bit-count.

The operation mode may alternate between a first mode and a second mode, and wherein a product of (i) the operable bit number and (ii) a number of bits of the first input data may be the same regardless of whether the operation mode is the first mode or the second mode.

The bit cells may include static random access memory (SRAM) bit cells.

The operation unit may include an accumulator configured to store the final operation result based on a result of performing operations between the first input data and the second input data and to accumulate the final operation result.

In another general aspect, an in-memory computing method includes: storing first input data having a reference-bit-count and receiving second input data also having the reference-bit-count; performing a multiplication operation between the first input data and the second input data using bit cells; outputting intermediate operation results by adding results of performing the multiplication operation output with respect to each of the bit cells; branching the intermediate operation results according to an operation mode; and outputting a final operation result based on a result of the branching.

The outputting of the intermediate operation results may include grouping the results based on a number of operation modes.

The branching may include determining a performing path of a shift operation corresponding to each of the intermediate operation results according to the operation mode; and performing a shift operation corresponding to each of the intermediate operation results based on the performing path.

The operation mode may include a first operation mode and a second operation mode, the intermediate operation results may include a first intermediate operation result and a second intermediate operation result, the branching may include delivering the first intermediate operation result and the second intermediate operation result without an additional shift according to the first operation mode, and outputting the final operation result may be done by adding the first intermediate operation result to the second intermediate operation result.

The operation mode may include a first operation mode and a second operation mode, the intermediate operation results may include a first intermediate operation result and a second intermediate operation result, the branching may include delivering the first intermediate operation result and the second intermediate operation result shifted by the reference-bit-count according to the second operation mode, and the outputting of the final operation result may include outputting the final operation result by adding the first intermediate operation result to the shifted second intermediate operation result.

The method may further include performing different bit-number operations according to the operation mode.

A number of operation modes may be determined based on a maximum bit number of an operable bit number and based on a bit number of the reference-bit-count.

A product of the operable bit number and a number of bits of the first input data may be the same regardless of the operation mode.

The bit cells may include static random access memory (SRAM) bit cells.

The method may further include storing the final operation result based on a result of performing operations between the first input data and the second input data and accumulating the final operation result. Other features and aspects will be apparent from the following detailed description, the drawings, and the claims.

### BRIEF DESCRIPTION OF THE DRAWINGS

FIG. 1 illustrates an example of implementation in-memory computing system for a multiply and accumulate (MAC) operation of a neural network, according to one or more embodiments.

FIG. 2 illustrates an example configuration of a memory device in an in-memory computing system, according to one or more embodiments.

FIG. 3 illustrates an example operation process of a first adder tree, according to one or more embodiments.

FIG. 4 illustrates an example structure of a memory device, according to one or more embodiments.

FIG. 5 illustrates an example operation of a demultiplexer, according to one or more embodiments.

FIG. 6 illustrates an example operation method of an in-memory computing system, according to one or more embodiments.

Throughout the drawings and the detailed description, unless otherwise described, the same or like drawing reference numerals will be understood to refer to the same or like elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

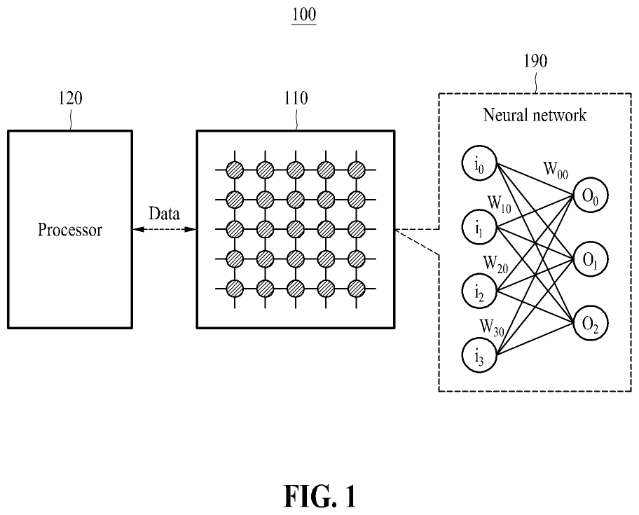

FIG. 1 illustrates an example in-memory computing system for a multiply and accumulate (MAC) operation of a neural network, according to one or more embodiments.

In the Von Neumann architecture, performance and power limitations occur due to frequent data movements between an operation unit and a memory unit. In-memory computing (IMC) is a computer architecture that performs operations directly inside a memory in which data is stored, reducing data movements between a processor 120 and a memory device 110 and increasing power efficiency. The processor 120 of an in-memory computing system 100 may input, to the memory device 110, data to which an operation is performed, and the memory device 110 may autonomously perform the operation. The memory device 110 can both perform a memory function of storing and retaining data and perform operations between the retained data and input data inputted to the memory device 110. The processor 120 may read an operation result from the memory device 110. Therefore, data transfer during the operation process may be minimized.

For example, the IMC system 100 may perform a MAC operation, which is frequently used in artificial intelligence (AI) algorithms among various operations. As illustrated in FIG. 1, a layer operation 190 in a neural network may include a MAC operation that adds up results obtained by multiplying each of input values of input nodes by a weight. As an example, the MAC operation may be represented in Equation 1.

$${O}_{0} = {\sum }_{m = 0}^{M - 1} {I}_{m} {W}_{0 , m} , {O}_{1} = {\sum }_{m = 0}^{M - 1} {I}_{m} {W}_{1 , m} , … , {O}_{T - 1} = {\sum }_{m = 0}^{M - 1} {I}_{m} {W}_{T - 1 , m} \qquad Equation 1$$

In Equation 1, Oₜ represents an output to a t-th node, Iₘ represents an m-th input, W_{t,m} represents a weight applied to an m-th input that is input to a t-th node. Here, Oₜ represents an output of a node or a node value, and is calculated as a weighted sum of an input Iₘ and a weight W_{t,m}. Here, m is an integer of 0 or more and M−1 or less, t is an integer of 0 or more and T−1 or less, and M and T are integers. M is the number of nodes of a previous layer connected to one node of a current layer, which is an operation target, and T is the number of nodes of the current layer.

The memory device 110 of the IMC system 100 according to an example may perform the MAC operation described above. The memory device 110 may also be referred to as a resistive memory device 110, a memory array, or an IMC device. However, the memory device 110 is not limited to being used for a MAC operation, and the memory device 110 may be used to drive any algorithm including memory storage and multiplication operations. A computing structure in which the memory device 110 according to an example directly performs an operation in memory without moving data is described below.

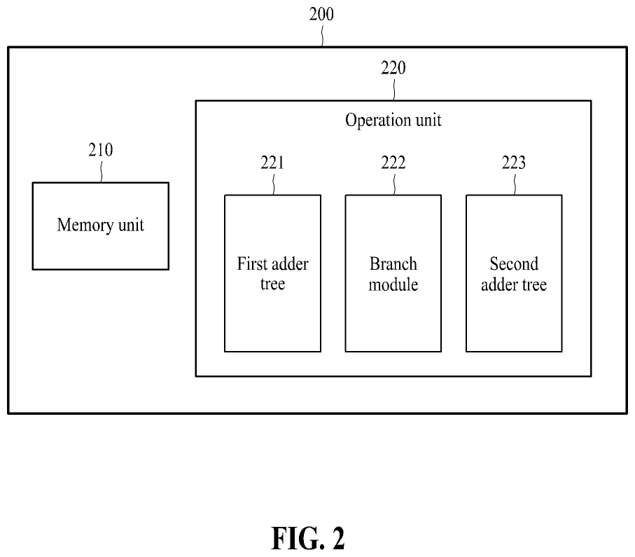

FIG. 2 illustrates a configuration of a memory device in an IMC system, according to one or more embodiments.

One or more blocks and combinations of blocks in FIG. 2 may be implemented by a special purpose hardware-based computer performing a specific function or a combination of special purpose hardware and computer instructions.

Referring to FIG. 2, a memory device 200 (e.g., the memory device 110 of FIG. 1) according to an example may include a memory unit 210 and an operation unit 220. The term such as “unit” or “device” used below refers to a unit that processes at least one function or operation, which may be implemented as hardware or software, or a combination of hardware and software.

In a digital IMC system and/or circuit, since all data is expressed as logical values and operations are performed, input values, weights, and output values may all have a binary format. Components described with reference to FIG. 2 may be implemented based on a digital logic circuit.

The memory unit 210 according to an example may include bit cells that store bit data (e.g., bit weights). Bit cells according to an example may also be referred to as “memory cells” or “memory matrices”. The bit cells may include, for example, at least one of a diode, a transistor (e.g., a metal-oxide-semiconductor field-effect transistor (MOSFET)), a static random access memory (SRAM) bit cell, or a resistive memory but are not limited thereto.

Although described in detail below, the memory device 200 according to an example may perform IMC capable of responding to various workloads by using a demultiplexer that changes an operation mode according to a reference-bit-count. The memory device 200 may reconfigure how it performs a MAC operation according to (and for) a particular neural network by adjusting the number of bits of the reference-bit-count, which may enable the memory device 200 to respond to varying bit-number accuracies of different types or instances of neural networks being processed.

The memory unit 210 according to an example may include bit cells that store first input data. The stored first input data may function as stored input data available to be operated on by the memory unit 210 as well as to function as the reference bit(s). While storing/retaining the first input data, the memory unit 210 may receive second input data of the reference-bit-count, and perform a multiplication operation between the first input data (first operand) and the second input data (a second operand).

The reference-bit-count may be a number of operation bit(s) for an inference operation of the neural network in the IMC system 100. For example, if the reference-bit-count input to the IMC system 100 is 4 bits, the memory device 200 may perform an operation on the 4-bit weight/4-bit input.

The first input data may include 4-bit weights of a neural network (the first input data is not limited to only weight data). The first input data may be stored in the bit cells included in the memory unit 210. For example, in a case of 64 MAT SRAM with “64” memory matrices (e.g., crossbar arrays, i.e., “MATs”), a 4-bit weight may be stored in the “64” memory matrices (MAT1 to MAT64). The number of memory matrices is not limited to the described example.

The second input data may also include 4-bit inputs. The memory unit 210 may perform multiplication operations between the 4-bit weights previously (and persistently) stored in the bit cells and the respective 4-bit inputs, which may be received from an input driver.

The memory device 200 according to an example may perform a MAC operation using the operation unit 220, among other components. The operation unit 220 according to an example may include an adder tree (e.g., a first adder tree 221 and a second adder tree 223) and a branch module 222.

Over time, the operation unit 220 may perform operations on different bit units (units of data, e.g., inputs/weights of different numbers of bits) according to an operation mode. For example, when the reference-bit-count is 8 bits, the operation unit 220 may operate in an operation mode for performing an 8-bit operation (e.g., weights/inputs of 8 bits), i.e., an 8-bit operation mode.

The first adder tree 221 may output intermediate operation results by adding results of multiplications performed on the bit cells of the memory unit 210. The results of performing one or more of the multiplication operations with one or more of the bit cells may be mapped to input terminal(s) of the first adder tree 221 based on the number of operation modes.

The branch module 222 may include a demultiplexer and an adder. The branch module 222 may branch the intermediate operation results according to an operation mode. The demultiplexer may determine, according to the operation mode, a performing path of a shift operation corresponding to each of the intermediate operation results. The adder may be connected to the demultiplexer to perform a shift operation corresponding to each of the intermediate operation results based on the performing path.

The term “module” used below may refer to a unit including one or a combination of two or more of, for example, hardware, software, or firmware. A “module” may be used interchangeably with terms such as, for example, unit, logic, logical block, component, or circuit. A “module” may be a minimum unit of an integrally formed component or a part thereof. A “module” may be a minimum unit that performs one or more functions or a part thereof. A “module” may be implemented mechanically or electronically. For example, a “module” may include at least one of a programmable-logic device, a field-programmable gate array (FPGA), or an application-specific integrated circuit (ASIC) chip that performs certain operations, which is known or to be developed.

The operation mode may be determined based on (i) a maximum operable bit number and (ii) the reference-bit-count. For example, if the memory device 200 supports a 4-bit operation and an 8-bit operation and the reference-bit-count is 4 bits, the operation mode of the memory device 200 may support a 4-bit operation mode and an 8-bit operation mode. In another example, if the memory device 200 supports a 4-bit, 8-bit, and 12-bit operations, and if the reference-bit-count is 4 bits, the operation mode of the memory device 200 may include a 4-bit operation mode, an 8-bit operation mode, and a 12-bit operation mode. The number of operation modes mentioned above may be the same as the number of operation modes supported by the memory device. However, the operation mode of the memory device 200 is not limited to the 4-bit, 8-bit, and 12-bit operation modes of the examples described in the present disclosure.

A product of the operable bit number and the number of bits of the first input data may be the same regardless of the operation mode. For example, assuming an IMC system in which the operable bit number is 4 bits, 8 bits, and 12 bits in 64 MAT SRAM, a product of the operable bit number and the first input data may be the same as 256. Accordingly, the first input data may include “64” data items in 4 bits, “32” data items in 8 bits, and “16” data items in 12 bits.

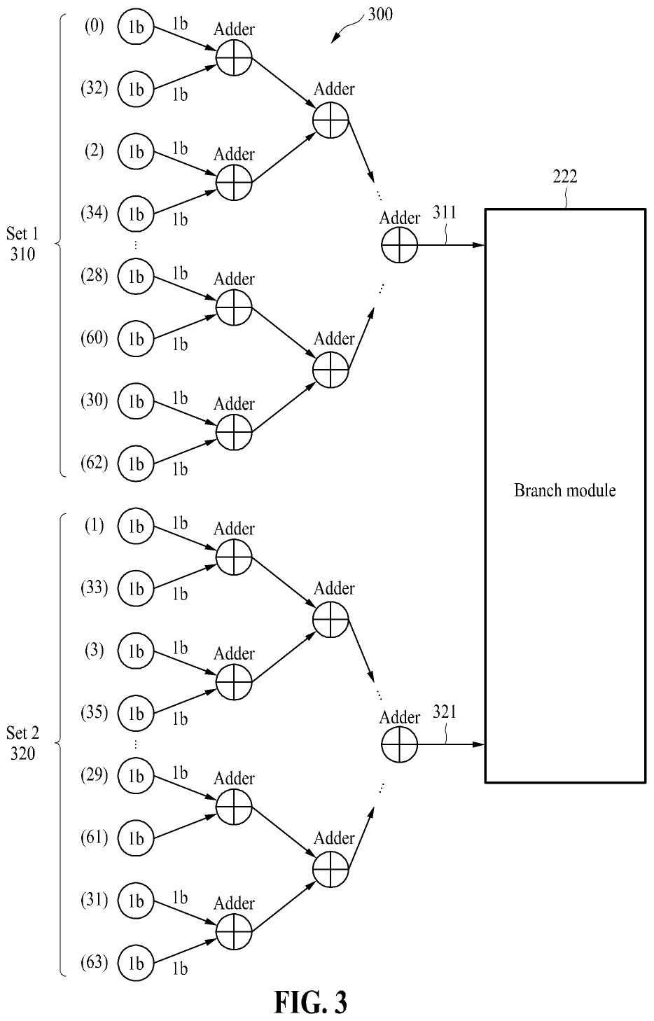

The second adder tree 223 may output a final operation result based on an output of the branch module 222. Operations of the first adder tree 221, the branch module 222, and the second adder tree 223 according to the operation mode of the operation unit 220 are described with reference to FIGS. 3 to 6.

The operation unit 220 may include an accumulator that accumulates final operation results output from the second adder tree.

FIG. 3 illustrates an example operation process of a first adder tree, according to one or more embodiments.

The descriptions given with reference to FIGS. 1 and 2 may be generally applied to the description of FIG. 3.

Referring to FIG. 3, when a memory device 200 according to an example supports 4-bit operation mode and 8-bit operation mode and a reference-bit-count is 4 bits, a first adder tree 300 (e.g., the first adder tree 221 of FIG. 2) may perform two sets of addition operations (e.g., Set 1 310 and Set 2 320). In the following description, a 4-bit operation mode is referred to as a first operation mode and an 8-bit operation mode is referred to as a second operation mode, and the memory device 200 may include the first operation mode and the second operation mode.

Results of performing a multiplication operations bit cells may be mapped to input terminals of the first adder tree 300 based on the number of operation modes. For example, when the number of operation modes is “two” (e.g., a 4-bit operation mode and an 8-bit operation mode), the results of performing the multiplication operations with the bit cells are divided into Set 1 310 and Set 2 320 and, based on the sets, the results are mapped to the input terminals of the first adder tree 300. The Set 1 310 may include results of multiplication operations on non-adjacent bit cells (e.g., <(0), (32)>, <(2), (34)>, . . . , <(30), (62)>, where <(x), (y)> indicates a pair of outputs that are added). Similarly, the Set 2 320 may include results of performing multiplication operations on non-adjacent bit cells (<(1), (33)>, <(3), (35)>, . . . , <(31), (63)>). However, in addition to mapping (<(0), (32)>, <(2), (34)>, . . . , <(30), (62)>), (<(1), (33)>, <(3), (35)>, . . . , <(31), (63)>) of the Set 1 310 and the Set 2 320 of the present disclosure, mapping (<(0), (4)>, <(2), (6)>, . . . , <(58), (62)>), (<(1), (5)>, <(3), (7)>, . . . , <(59), (63)>) may be possible, and the mappings in each set may be arbitrarily changed and are not limited to the described examples.

The first adder tree 300 according to an example may output a first intermediate operation result 311 (e.g., for Set 1 310) and a second intermediate operation result 321 (e.g., for Set 2 320). The first intermediate operation result 311 and the second intermediate operation result 321 may be input to the branch module 222.

In the first operation mode (e.g., 4-bit), the branch module 222 according to an example may deliver the first intermediate operation result 311 and the second intermediate operation result 321 to the second adder tree 223 according to the first operation mode. A demultiplexer of the branch module 222 may receive a signal related to the first operation mode and may deliver the first intermediate operation result 311 and the second intermediate operation result 321 to the second adder tree 223 according to the signal. For example, when the operation reference-bit-count of the memory device 200 is 4 bits, the branch module 222 may deliver the first intermediate operation result 311 of 6 bits and the second intermediate operation result 321 of 6 bits to the second adder tree 223 according to the first operation mode (such delivery may be via a first path within the branch module 222). The second adder tree 223 may output a final operation result by adding the first intermediate operation result to the second intermediate operation result.

In the second operation mode, according thereto, the branch module 222 according to an example may deliver the first intermediate operation result 311 and the second intermediate operation result 321 shifted by the reference-bit-count to the second adder tree 223. The demultiplexer of the branch module 222 may receive a signal related to the second operation mode and may deliver the first intermediate operation result 311 and the second intermediate operation result 321 to an adder. The adder of the branch module 222 may shift the second intermediate operation result 321 by the reference-bit-count. For example, when an operation reference-bit-count of the memory device 200 is 8 bits, according to the first operation mode, the demultiplexer of the branch module 222 may deliver the first intermediate operation result 311 of 6 bits and the second intermediate operation result 321 of 6 bits to the adder (such deliver may be via a second path within the branch module 222). The second adder tree 223 may output a final operation result by adding the first intermediate operation result to the shifted second intermediate operation result.

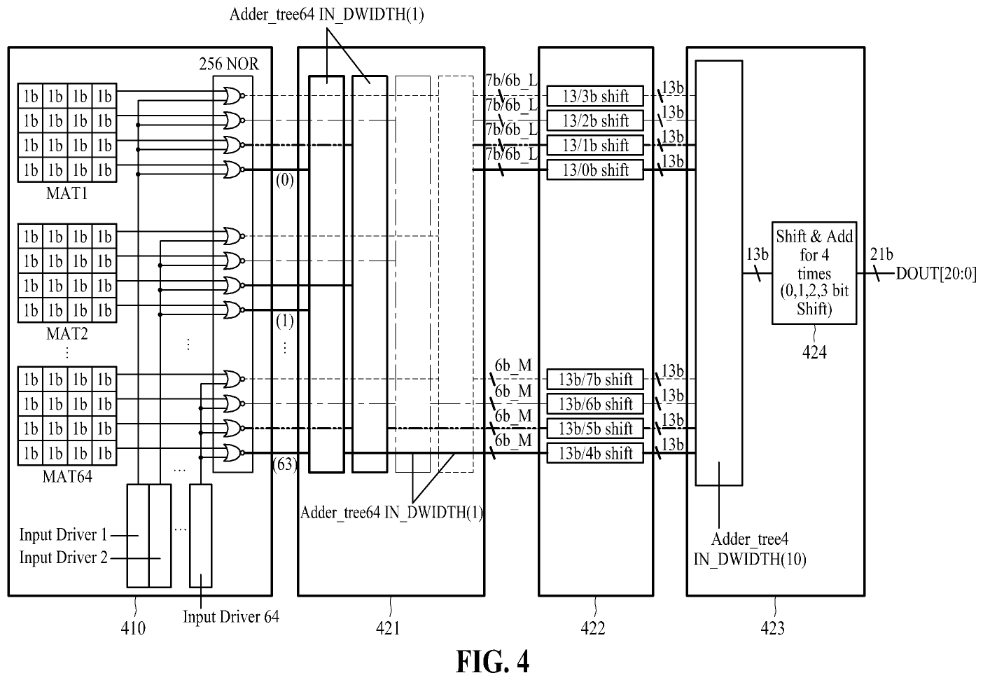

FIG. 4 illustrates structure of a memory device, according to one or more embodiments.

The descriptions given with reference to FIG. 1 or 2 may be generally applied to the description given with reference to FIG. 4.

The description given with reference to FIG. 4 represents an example of an operation process of a memory device 200 when operable bits in 64 MAT SRAM are 4 bits and 8 bits, where the operable bits are numbers of bits of operands for the operations, e.g., multiplications.

A memory unit 410 (e.g., the memory unit 210 of FIG. 2) according to an example may include pluralities (e.g., 64) of bit cells (e.g., MAT1 to MAT64) and 256 NOR gates (for performing the multiplication operations). For example, if a reference-bit-count is 4 bits, first input data may be stored by 1 bit in a 4×4 memory matrix of bit cells. The NOR gates may receive the first input data from the pluralities of bit cells and second input data of the reference-bit-count from input drivers (e.g., Driver1 to Driver64), and may perform a multiplication operation between the first input data and the second input data. Results of performing the multiplication operation may be input to a first adder tree 421.

The first adder tree 421 (e.g., the first adder tree 221 of FIG. 2 and the first adder tree 300 of FIG. 3) according to an example may include as many adder trees as the number of bits of the reference-bit-count. For example, if the reference-bit-count is 4 bits, the number of adder trees (Adder_tree64 IN_DWIDTH(1)) included in the first adder tree 421 may be “4”. The adder trees included in the first adder tree 421 may receive “64” 1-bit inputs and may perform an addition operation thereon. As described above with reference to FIG. 3, each adder tree may divide the inputs into two sets and may perform the addition operation.

A branch module 422 (e.g., the branch module 222 of FIG. 2) according to an example may include a demultiplexer and an adder. The branch module 422 may determine an operation mode based on an operable bit number supported by the memory device 200. For example, if the number of operation bits required by an IMC system is 4 bits, the branch module 422 may deliver an operation result of the first adder tree 421 to a second adder tree 423 through a first path that does not go through the adder by using the demultiplexer. In another example, if the number of operation bits required by the IMC system is 8 bits, the branch module 422 may shift a part of the operation result of the first adder tree 421 and may deliver the shifted operation result to the second adder tree 423 through a second path that goes through the adder, which may be done by using the demultiplexer.

The second adder tree 423 (e.g., the second adder tree 223 of FIG. 2) according to an example may output a final operation result based on the output of the branch module 222.

An accumulator 424 according to an example may store the final operation results based on the results of operations between the first input data and the second input data, and may accumulate the final operation results.

More specifically, referring to FIG. 4, in a case of 8-bit operations, a 6b final output (hereinafter, referred to as 6b_L) of Set 1 (e.g., the Set 1 310 of FIG. 3 (<(0), (32)>, . . . , <(30), (62)>)) and a 6b final output (hereinafter, referred to as 6b_M) of Set 2 (e.g., the Set 2 320 of FIG. 3 (<(1), (33)>, . . . , <(31), (63)>)) are regarded as least significant bit (LSB) and most significant bit (MSB), respectively, and in the case of 6b_M, an 8b operation may be possible by additionally shifting and adding 4 bits. As a result, when the reference-bit-count is 4 bits, in the case of the 8 bit operation, the number of equivalent (effective) memory matrices may become “32”, using “64” matrices, in a process of converting a 4b weight to an 8b weight, so an 8b input/8b weight/32MAT operation may be performed. As a result of performing the above operation, 8-bit operation may output a maximum of 255×255×32 (having a final output/result of 21 bits). When 4-bit operation is used, a result is output through the first path, which does not go through the adder, so the 14 least significant bits out of the entire 21 output bits is used to as the final output/result.

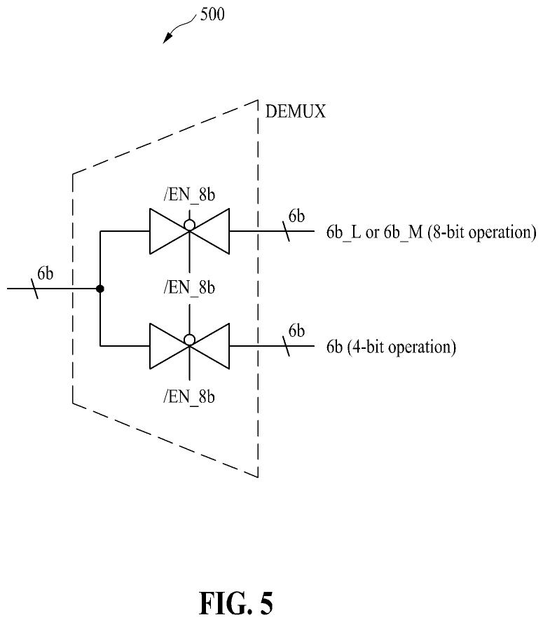

FIG. 5 illustrates an operation of a demultiplexer, according to one or more embodiments.

The descriptions given with reference to FIGS. 1 to 4 may generally apply to the description given with reference to FIG. 5.

Referring to FIG. 5, a demultiplexer 500 according to an example may be included in a branch module (e.g., the branch module 222 of FIG. 2 and the branch module 422 of FIG. 3). The demultiplexer 500 may branch a 6-bit input according to an operation mode. For example, the demultiplexer 500 may determine whether to deliver the 6-bit input through a 4-bit operation path (a first path) or through an 8-bit operation path (a second path), in response to an 8-bit operation enable signal (EN_8b).

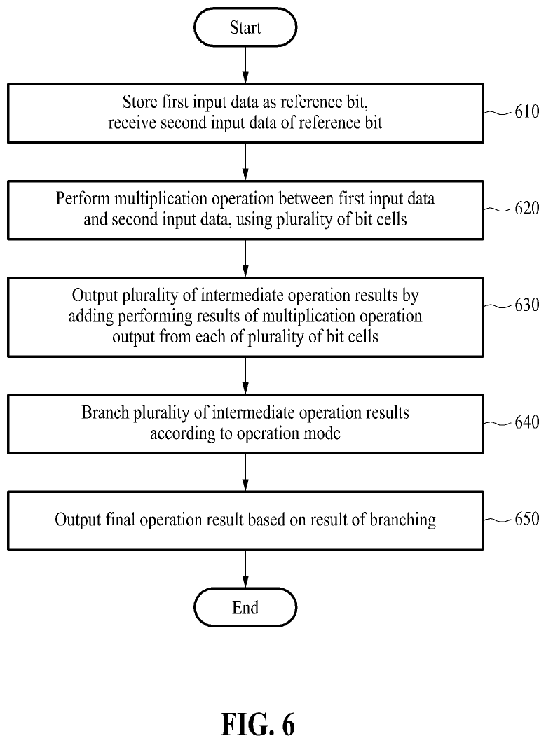

FIG. 6 illustrates an operation method of an IMC system, according to one or more embodiments.

The descriptions given with reference to FIGS. 1 to 5 may be generally applied to the description of FIG. 6.

For convenience of description, operations 610 to 650 are described as being performed using the memory device 200 illustrated in FIG. 2. However, these operations 610 to 650 may be used by any other suitable electronic device in any suitable system.

In operation 610, the memory device 200 may store first input data having a reference-bit-count and receive second input data also having the reference-bit-count.

In operation 620, the memory device 200 may perform a multiplication operation between the first input data and the second input data, using a plurality of bit cells. The plurality of bit cells may include SRAM bit cells.

In operation 630, the memory device 200 may output intermediate operation results by adding results of performing a multiplication operation output with respect to each of the bit cells. The memory device 200 may group the results of performing the multiplication operation output with respect to the bit cells based on the number of operation modes. The memory device 200 may perform different bit-number operations according to an operation mode. The number of operation modes may be determined based on a maximum bit number of an operable bit number and based on the reference-bit-count. A product of the operable bit number and the number of bits of the first input data may be the same regardless of the operation mode.

The operation mode may include a first operation mode and a second operation mode. The intermediate operation results may include a first intermediate operation result and a second intermediate operation result.

The memory device 200 may deliver the first intermediate operation result and the second intermediate operation result without an additional shift according to the first operation mode. The memory device 200 may output a final operation result by adding the first intermediate operation result to the second intermediate operation result.

The memory device 200 may deliver the first intermediate operation result and the second intermediate operation result shifted by the reference-bit-count according to the second operation mode. The memory device 200 may output the final operation result by adding the first intermediate operation result to the shifted second intermediate operation result.

In operation 640, the memory device 200 may branch (form/select a performing path for) the intermediate operation results according to an operation mode. The memory device 200 may determine a performing path of a shift operation corresponding to each of the plurality of intermediate operation results according to the operation mode. The memory device 200 may perform the shift operation corresponding to each of the intermediate operation results based on the performing path.

In operation 650, the memory device 200 may output the final operation result based on a result of the branching. The memory device 200 may store the final operation results based on a result of performing operations between the first input data and the second input data, and may accumulate the final operation results.

The computing apparatuses, the electronic devices, the processors, the memories, the information output system and hardware, the storage devices, and other apparatuses, devices, units, modules, and components described herein with respect to FIGS. 1-6 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-6 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An in-memory computing device comprising:
a memory unit comprising bit cells configured to store first input data having a reference-bit-count, receive second input data also having the reference-bit-count, and perform a multiplication operation between the first input data and the second input data; and
an operation unit comprising:
a first adder tree configured to output intermediate operation results by adding results of performing the multiplication operation output with respect to each of the bit cells;
a branch module configured to branch the intermediate operation results according to an operation mode of the in-memory computing device; and
a second adder tree configured to output a final operation result based on an output of the branch module.

2. The in-memory computing device of claim 1, wherein the results of performing the multiplication operation are mapped to an input terminal of the first adder tree based on a number of operation modes.

3. The in-memory computing device of claim 1, wherein the branch module comprises:
a demultiplexer configured to determine a performing path of a shift operation corresponding to each of the intermediate operation results according to the operation mode; and
an adder connected to the demultiplexer to perform a shift operation corresponding to each of the intermediate operation results based on the performing path.

4. The in-memory computing device of claim 1, wherein
the operation mode comprises a first operation mode and a second operation mode,
the first adder tree is configured to output a first intermediate operation result and a second intermediate operation result,
the branch module is configured to deliver the first intermediate operation result and the second intermediate operation result to the second adder tree according to the first operation mode, and
the second adder tree is configured to output the final operation result by adding the first intermediate operation result to the second intermediate operation result.

5. The in-memory computing device of claim 1, wherein
the operation mode comprises a first operation mode and a second operation mode,
the first adder tree is configured to output a first intermediate operation result and a second intermediate operation result,
the branch module is configured to deliver the first intermediate operation result and the second intermediate operation result shifted by the reference-bit-count to the second adder tree according to the second operation mode, and
the second adder tree is configured to output the final operation result by adding the first intermediate operation result to the shifted second intermediate operation result.

6. The in-memory computing device of claim 1, wherein the operation unit is configured to perform different bit-number operations depending on the operation mode.

7. The in-memory computing device of claim 1, wherein a number of operation modes is determined based on a maximum bit number of an operable bit number and a bit number of the reference-bit-count.

8. The in-memory computing device of claim 7, wherein the operation mode can alternate between a first mode and a second mode, and wherein a product of (i) the operable bit number and (ii) a number of bits of the first input data is the same regardless of whether the operation mode is the first mode or the second mode.

9. The in-memory computing device of claim 1, wherein the bit cells comprises static random access memory (SRAM) bit cells.

10. The in-memory computing device of claim 1, wherein the operation unit comprises an accumulator configured to store the final operation result based on a result of performing operations between the first input data and the second input data and to accumulate the final operation result.

11. An in-memory computing method comprising:
storing first input data having a reference-bit-count and receiving second input data also having the reference-bit-count;
performing a multiplication operation between the first input data and the second input data using bit cells;
outputting intermediate operation results by adding results of performing the multiplication operation output with respect to each of the bit cells;
branching the intermediate operation results according to an operation mode; and
outputting a final operation result based on a result of the branching.

12. The in-memory computing method of claim 11, wherein
the outputting of the intermediate operation results comprises grouping the results based on a number of operation modes.

13. The in-memory computing method of claim 11, wherein the branching comprises:
determining a performing path of a shift operation corresponding to each of the intermediate operation results according to the operation mode; and
performing a shift operation corresponding to each of the intermediate operation results based on the performing path.

14. The in-memory computing method of claim 11, wherein
the operation mode comprises a first operation mode and a second operation mode,
the intermediate operation results comprises a first intermediate operation result and a second intermediate operation result,
the branching comprises delivering the first intermediate operation result and the second intermediate operation result without an additional shift according to the first operation mode, and
outputting the final operation result by adding the first intermediate operation result to the second intermediate operation result.

15. The in-memory computing method of claim 11, wherein
the operation mode comprises a first operation mode and a second operation mode,
the intermediate operation results comprise a first intermediate operation result and a second intermediate operation result,
the branching comprises delivering the first intermediate operation result and the second intermediate operation result shifted by the reference-bit-count according to the second operation mode, and
the outputting of the final operation result comprises outputting the final operation result by adding the first intermediate operation result to the shifted second intermediate operation result.

16. The in-memory computing method of claim 11, further comprising performing different bit-number operations according to the operation mode.

17. The in-memory computing method of claim 11, wherein
a number of operation modes is determined based on a maximum bit number of an operable bit number and based on a bit number of the reference-bit-count.

18. The in-memory computing method of claim 17, wherein a product of the operable bit number and a number of bits of the first input data is the same regardless of the operation mode.

19. The in-memory computing method of claim 11, wherein the bit cells comprise static random access memory (SRAM) bit cells.

20. The in-memory computing method of claim 11, further comprising storing the final operation result based on a result of performing operations between the first input data and the second input data and accumulating the final operation result.
